(19) United States
(12) Patent Application Publication
(10) Pub. No.: US 2025/0031579 A1
(43) Pub. Date: Jan. 23, 2025

(54) LAMINATED VEHICLE GLASS STRUCTURES INCLUDING THREE-DIMENSIONAL PRINTED PIEZOELECTRIC SPEAKERS FOR SOUND GENERATION

(71) Applicant: GM GLOBAL TECHNOLOGY OPERATIONS LLC, Detroit, MI (US)

(72) Inventors: Julien P. Mourou, Bloomfield Hills, MI (US); Bo Yang, Rochester Hills, MI (US); Gerard Parij, Warren, MI (US); Bradley Allen Newcomb, Troy, MI (US)

(21) Appl. No.: 18/354,071

(22) Filed: Jul. 18, 2023

(51) Int. Cl. H10N 30/30; H04R 7/04; H04R 17/00; H10N 30/072; H10N 30/074; H10N 30/88

(52) U.S. Cl. CPC H10N 30/308; H04R 7/045; H04R 17/005; H10N 30/072; H10N 30/074; H10N 30/88; H04R 2499/13

(57) ABSTRACT

Laminated vehicle glass structures included printed piezoelectric actuators for sound generation. Ring-shaped piezoelectric actuators are printed on an inner surface of a selected one of the exterior glass panel or interior glass panel. The printed piezoelectric actuators are offset relative to a centerline longitudinally extending between the opposing glass panels. Also disclosed are processes for forming the laminated glass structures including at least one printed piezoelectric actuator. The laminated glass structures can be utilized about the vehicle anywhere sound generation is desired, e.g., passenger windows, sunroofs, front windshield, rear windshield, and the like. The printed ring-shaped piezoelectric actuators act as a diaphragm to produce sound upon excitation.

### INTRODUCTION

The subject disclosure relates to laminated vehicle glass structures, and more particularly, to laminated vehicle glass structures including printed piezoelectric speakers within the laminated glass structure for sound generation, wherein the piezoelectric speakers are ring shaped piezoelectric actuators printed on a selected glass surface prior to lamination such that the printed piezoelectric speaker is embedded in a laminating material within the laminated glass structure.

Current speaker technology utilized in vehicles generally employs a moving coil and cone technology that is selectively placed within doors, instrument panels, roofing, and elsewhere throughout the vehicle to produce sound. The speakers function as transducers to convert amplified electrical waves from an infotainment system, phone, or the like into sound pressure waves that propagate in the air for vehicle occupants to hear. An amplifier feeds a signal to two terminals on a back-side of the speaker. These terminals pass the current into a cylindrical coil of wire, which is suspended in a circular gap between the poles of a permanent magnet. This coil moves back and forth inside the magnetic field as the current passing through it alternates in a direction with the applied signal, per Faraday's law. The center of the speaker cone is attached to one end, which gets driven back and forth by the moving coil. This cone is held at its edges by an airtight suspension or surround. As the cone moves, it pushes and pulls the surrounding air; by doing so it creates pressure waves in the air in the form of sound.

Coil and cone type speakers can add substantial weight to a vehicle, require individual installation and connection, occupy valuable interior trim space, allow significant road noise intrusion, and are subject to substantial shock and environmental abuse. Moreover, because of the limited trim space available for speaker placement, the speakers can be poorly positioned for listening. Their on-axis radiation is typically directed low in the vehicle towards a seated occupants' legs and midsection rather than at the occupants' cars. As such, the direct sound from the speaker to the listener is typically far off-axis and highly variable in frequency response with typically insufficient high frequencies. In the high noise environment of a vehicle, this often results in mid- and high-frequency audio information getting lost. “Imaging”, the perception of where sound is coming from, is also adversely affected since the loudspeakers are typically mounted low in the vehicle; for the front passengers, the audio image is pulled down into the doors while the rear passengers have an image to the side or rear instead of what should be presented in front of them.

Accordingly, it is desirable to better position the speakers within the vehicle while minimizing trim space requirements, weight, road intrusion noise, abuse, and the like.

### SUMMARY

In one exemplary embodiment, a laminated glass structure for a vehicle includes an outer glass panel, an inner glass panel, and a laminating material therebetween. The outer glass panel includes an outer surface facing an environment about the vehicle and an inner surface. The inner glass panel includes an outer surface facing an interior of the vehicle and an inner surface. The laminating material is intermediate the outer and inner glass panels and bonded to the inner surfaces of the outer and inner glass panels. The laminated glass structure further includes at least one printed ring-shaped piezoelectric actuator on a frit material, wherein the at least one printed ring-shaped piezoelectric actuator and the frit material are embedded within the laminating material and offset relative to a centerline longitudinally extending between the first and second glass panels. In one or more aspects, the at least one printed ring-shaped piezoelectric actuator is printed on the inner surface of the outer glass panel. In other aspects, the at least one printed ring-shaped piezoelectric actuator is printed on the inner surface of the inner glass panel. In still other aspects, the at least one of the printed ring-shaped piezoelectric actuator is printed on the inner surface of the inner glass panel and printed on the inner surface of the outer glass panel.

The at least one printed ring-shaped piezoelectric actuator can include a first conductive layer on the frit material, a piezoelectric material on the first conductive layer, and a second conductive layer on the piezoelectric material, wherein the at least one printed ring-shaped piezoelectric actuator has an oval-shape, a circular shape, and/or a polygonal shape. In one or more aspects, the laminating material includes polyvinyl butyral resin or ethylene vinyl acetate. In one or more embodiments, the laminated glass structure further includes a plastic layer configured to provide solar reflectivity within the laminating material and is intermediate the inner and outer glass panels. In one or more aspects, the outer glass has a thickness within a range of about 1.6 to about 3.5 millimeters, the inner glass panel has a thickness of the about 0.7 millimeters to about 3.5 millimeters, the laminating material has a thickness in a range of about 0.3 millimeters to about 2.0 millimeters, and the at least one printed ring-shaped piezoelectric actuator has a thickness less than the laminating material. The frit material has a width greater than a width of the printed ring-shaped piezoelectric actuator and can be printed onto the selected inner glass surface. The frit material can be semi-transparent. In one or more aspects, the piezoelectric material can be lead zirconium titanate.

In another exemplary embodiment, a process of forming a laminated glass structure for a vehicle includes printing a ring pattern of a frit material on an inner surface of a selected glass panel. A first conductive layer is then printed onto the ring pattern of the frit material. A piezoelectric material is printed onto the first conductive layer and a second conductive layer is printed onto the piezoelectric material to form a piezoelectric actuator. The selected glass panel, a sheet of laminating material; and another glass panel are stackedly arranged, wherein the inner surface of the selected glass panel contacts the sheet of laminating material and the another glass panel includes an inner surface contacting the sheet of laminating material such that the sheet of laminating material is sandwiched therebetween. Heat and pressure are applied to laminate the selected glass panel to the another glass panel, wherein the piezoelectric actuator on the ring pattern of the frit material have a height dimension less than a thickness of the sheet of laminating material. The sheet of laminating material can include polyvinyl butyral resin or ethylene vinyl acetate. In one or more aspects, printing the frit material, the first and second conductive layers and the piezoelectric material includes robotically depositing droplets of the frit material, the first and second conductive layers, and the piezoelectric material to form the piezoelectric actuator. In other aspects, printing the frit material, the first and second conductive layers and the piezoelectric material comprises ink jet printing, screen printing, additive manufacturing, etching or combinations including at least one thereof. The printed piezoelectric material can include lead zirconium titanate, wherein the ring-shaped pattern can include a circular-shape, an oval-shape, or a polygonal-shape.

In yet another exemplary embodiment, a laminated glass structure for a vehicle includes an outer glass panel, an inner glass panel and a laminating material therebetween. The outer glass panel has a thickness of about 1.6 to about 3.5 millimeters and includes an outer surface exposed to an environment about the vehicle and an inner surface. The inner glass panel has a thickness of about 0.7 millimeters to about 3.5 millimeters and includes an inner surface and an outer surface exposed an interior of the vehicle. The laminating material has a thickness of about 0.3 millimeters to about 2 millimeters between the outer glass panel and the inner glass panel and is in contact with the inner surfaces of the outer and inner glass panels. The laminating material is a polyvinyl butyral resin or an ethylene vinyl acetate. A printed piezoelectric actuator having a thickness less than the laminating material and in a shape of a ring having a thickness less than an actual thickness of the laminating material is provided on a selected inner glass surface and is offset relative to a centerline extending between the inner surfaces of the outer and inner glass panels and are in contact with a selected one of the inner surfaces of the outer glass panel or the inner glass panel, The laminated glass structure forms a fixed glass roof system, a movable glass roof system, a front windshield, a rear quarter glass, a side moving glass, and/or a non-movable side glass.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a top-down view of a ring-shaped piezoelectric actuator provided within a laminated glass structure in accordance with one or more embodiments of the present disclosure;

FIG. 2 is an enlarged cross-sectional view taken along lines A-A of FIG. 1 illustrating various printed layers defining a ring-shaped piezoelectric actuator embedded within a laminated glass structure in accordance with one or more embodiments of the present disclosure;

FIG. 3 is a cross sectional view of a laminated glass structure including a ring-shaped piezoelectric actuator printed on an inner surface of an exterior glass panel of a laminated glass structure in accordance with one or more embodiments of the present disclosure; and

FIG. 4 is a cross sectional view of a laminated glass structure including a ring-shaped piezoelectric actuator printed on an outer surface of an interior glass panel of a laminated glass structure in accordance with one or more embodiments of the present disclosure.

### DETAILED DESCRIPTION

The following description is merely exemplary in nature and is not intended to limit the present disclosure, its application or uses.

In accordance with an exemplary embodiment, laminated glass structures for vehicles are provided and include one or more printed piezoelectric actuators within the laminated glass structure, which can be printed as a three-dimensional structure on a selected inner glass surface within the laminated glass structure corresponding to the exterior or interior glass panels. Regulated power can be supplied to the piezoelectric actuators via the vehicle infotainment system, for example. In one or more embodiments, an infotainment amplifier system can be electrically coupled to the piezoelectric actuators using patterned conductive coatings provided directly on the selected inner glass surface within the laminated glass structure and/or through the use of negative and positive wires, which are electrically coupled to the piezoelectric actuator, which may or may not be insulated if sufficiently spaced apart from one another. In the case of patterned conductive wires within the laminate structure, a conductive surface can be first applied and subsequently patterned on selected inner surfaces of the glass panels or on a selected surface of a plastic layer, if present, within the laminating material.

Although reference will be made throughout this application to two glass panels defining the laminated glass structure, it should be apparent that more than two glass panels could be utilized although the increases in weight would make this less practical. The laminated glass structures including the one or more embedded piezoelectric actuators according to the present disclosure can be used in vehicles wherever laminated glass assemblies are utilized including, for example, fixed glass roofing systems, front windshields, side moving glasses, rear quarter glasses, rear glasses, and the like. Unlike coil and cone-based speakers, the piezoelectric actuators advantageously occupy minimal space, are of significantly lower weight, can be used to occupy space within the vehicle previously not used for speaker placement, (i.e., in the laminated glass structure), and can be located above and/or next to the occupant(s) as opposed to coil and cone speakers, which are often placed within trim panels well below the vehicle windows, (e.g., door panels).

Piezoelectric actuators are generally transducer devices that convert electrical energy into a mechanical displacement or stress based on a piezoelectric effect or vice versa. The piezoelectric effect is defined as the ability of some materials to change their shape or size in response to an applied electric field. In the present disclosure, the printed piezoelectric actuators have a ring shape and can convert electrical energy into vibrations to generally function as a diaphragm in a manner similar to a coil and cone speakers to produce sound.

The process for printing the piezoelectric actuators generally includes printing a desired pattern of a (glass or ceramic) frit material, which can be non-transparent or semi-transparent depending on the frit composition: printing a conductive layer onto the patterned glass frit material, and printing a slurry of a powdered piezoelectric material onto the patterned conductive layer to form a piezoelectric-ceramic layer. The particular method of printing is not intended to be limited and can include screen printing, ink jet printing, etching, aerosol jet printing. 3D printing, droplet printing, selective laser sintering, extrusion free forming, stereo lithography, digital light processing, laminated object manufacturing, and the like. The process can further include robotic ink jet deposition of the various materials and layers defining the printed piezoelectric actuators. For example, the method can include robotic deposition of about 80 microns to about 100-micron-sized droplets of each of the non-conductive frit material, the conductive paste, and the piezoelectric material, wherein the ring-shaped geometry can be tuned to provide the desired sound quality, geometry, aesthetics, durability, transparency, mass, and the like.

The laminated glass structures include first and second glass panels (including the printed piezoelectric actuators on selected inner surfaces thereof) and one or more sheets of a laminating material that are stackedly arranged such that the laminating material is intermediate the first and second glass panels. Selected inner glass surfaces of these panels include one or more of the three-dimensionally printed piezoelectric actuators, which are configured to contact the sheet of laminating material during assembly. The assembly is then subjected to heat and pressure to cohesively bond the first and second glass panels together and form the laminated glass assembly. In this manner, the three-dimensionally printed piezoelectric actuators are in contact with a selected one of the inner glass surfaces and embedded in the laminating material. Additionally, because the piezoelectric actuators are printed onto a selected one of the inner glass surfaces of the first or second glass panel, subsequent lamination results in the three-dimensionally printed piezoelectric actuators being offset relative to a centerline longitudinally extending between the first and second glass panels, which produces maximum sound output.

As previously noted, the laminated glass assemblies including the printed piezoelectric actuators can be used in vehicles wherever laminated glass assemblies are utilized including, for example, a glass roof, front and rear windshields, passenger windows, and the like. Unlike coil and cone-based speakers, the printed piezoelectric actuators advantageously occupy minimal space, can be of any printed pattern and configuration including decorative designs, can be formed of semi-transparent material, are low weight, can be used to occupy space within the vehicle previously not used for speaker placement, (i.e., within the laminated glass structure), and can be located above and/or next to the occupant(s) within the glass laminate as opposed to coil and cone speakers, which are often placed within trim panels below the vehicle windows, (e.g., door panels) or occupy valuable roofing space, which can limit the size of laminated glass roofing panels since the traditional cone and coil-based speakers are not attached to the glass.

Conventional techniques related to laminated glass manufacturing processes for vehicles may or may not be described in detail herein. Moreover, the various tasks and process steps described herein can be incorporated into a more comprehensive procedure or process having additional steps or functionality not described in detail herein. In particular, various steps in the windshield manufacturing processes are well known and so, in the interest of brevity, many conventional steps will only be mentioned briefly herein or will be omitted entirely without providing the well-known process details.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects. Additionally, the terms “upper”, “lower”, “top”, “bottom”, “left,” and “right,” and derivatives thereof shall relate to the described structures, as they are oriented in the drawing figures. The same numbers in the various figures can refer to the same structural component or part thereof.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

As noted above, the glass panels for vehicles are generally laminated glass structures including an exterior glass panel and an interior glass panel laminated together using one or more sheets of a polymeric laminating material. The laminated structure can be used as front windshields, rear glass, fixed glass roof systems, moving glass roof systems, side moving glass, rear quarter glass, movable and static passenger windows, and the like.

The laminated glass structures are generally formed from curved or planar glass panels having a shape intended for its end use. For example, roofing applications generally utilize rectangular shaped planar or curved glass panels that are laminated together. Known glass panels can be made of heat-ray absorbing glass, regular clear glass, green glass, or UV green glass. In some embodiments, adjustments can be made so that the exterior glass panel ensures a desired solar and/or tint absorptance and the inner glass panel provides visible light transmittance. Moreover, additional sheets within the laminated glass structure can also be used to provide certain features. For example, a plastic layer can be utilized within the laminated structure to provide solar reflectively.

Although there is no particular limitation on the thickness of the laminated glass structure, for a roof application the total thickness of the outer glass panel is generally set to about 1.6 to about 3.5 millimeters (mm) and the inner glass panel is generally set to about 0.7 to about 3.5 mm. The laminating material can have a thickness within a range of about 0.3 mm to about 2 mm, although greater or lesser thickness can be utilized. In one or more embodiments, the thickness of the laminating material is about 0.76 mm.

The process of laminating the laminated glass structure generally includes application of heat and pressure to bond two or more layers of glass together with a layer of laminating material such as polyvinyl butyral, ethylene vinyl acetate, or the like, in between. The laminating material is usually melted and/or softened by the heat, allowing it to bond opposing glass layers together and create a strong, durable laminate structure. The temperature range for laminating glass is typically between 120° C. and 150° C. (248° F. and 302° F.), although some processes may use higher or lower temperatures depending on the materials and equipment being used. The pressure range for laminating glass can vary widely depending on the specific lamination process, but it is typically between 10 and 15 psi (0.7 and 1 bar). Some processes may use higher pressures to achieve a stronger bond, while others may use lower pressures to reduce the risk of damaging the glass. In some applications, a mask layer (i.e., frit layer) can be formed of a ceramic, metal or the like can be provided about the periphery of one or both glass panels prior to lamination.

In one or more embodiments, a laminated glass structure for a vehicle includes a printed piezoelectric actuator provided within the polymeric laminating material used to laminate a first glass panel to a second glass panel. The printed piezoelectric actuator is configured to be asymmetrically disposed relative to a distance to the exterior and interior glass panels within a thickness of the polymeric laminating material. It has been found that if the piezoelectric actuator is the same thickness as the polymeric laminating material and contacts the inner surfaces of each glass panel, the vibrations are at opposite phase and cancel each other out, thereby producing no sound. Likewise, no sound will be produced if the piezoelectric actuator is situated within the middle (i.e., equidistant from opposing inner glass surfaces) of the polymeric laminating material. For example, a laminated glass structure including two polymeric laminating sheets of the same thickness and a piezoelectric actuator printed onto a selected one of the sheet surfaces without contact to either inner surface of the exterior facing glass panel or the inner surface of the interior glass panel and at the same distance to each respective inner surface of the glass panels, will produce no sound. The vibrations of the piezoelectric actuator from each respective glass panel would be at opposite phases and cancel each other out so that no sound is emitted. However, if the piezoelectric actuator is configured to have a thickness less than the polymeric laminating material so that it is at least partly embedded and contacts or is in closer proximity to either the inner surface of the exterior glass panel or the interior glass panel, the vibrations from the selected inner surface of the exterior or interior glass panels will be of the same phase and provide sound.

The process for printing the ring-shaped piezoelectric actuators generally includes printing a glass frit pattern in a ring-shaped pattern onto a selected inner surface of an exterior or interior glass panel in the laminated glass structure. Reference to “inner surface” generally refers to a surface of a respective glass panel in contact with the laminating material when the exterior glass panel, the laminating material, and the interior panel are stackedly arranged and subsequently subjected to heat and pressure to form the laminated glass structure. The ring-shaped pattern of the frit material can be made during application of the masking material or subsequent to deposition of the masking material and a subsequent etching process to form the pattern.

A first conductive layer of conductive paste is deposited onto the ring-shaped pattern of the glass frit material, which has a width that is generally smaller than the pattern width provided for the glass frit material.

A piezoelectric material such as lead zirconium titanate is deposited onto the first conductive layer.

A second conductive layer of conductive paste is deposited onto the piezoelectric material, which can be the same or different as the first conductive paste. The various layers of the piezoelectric actuator as deposited can be annealed and sintered prior to or during the subsequent laminating process.

Exemplary glass frit materials include fused, quenched and granulated ceramic composites of a calcinated mixture of sand and fluxes. It is deposited in dots on the windshield to create varying degrees of non-transparency or semi transparency by digital deposition, silk screening, chemical vapor deposition, physical vapor deposition, and the like. The ceramic composite can be applied as a glass flux and fired at around 550° C. with a typical composition of 60-85% of Bi, B, Zn, Si oxides, a stain of 15-40% with oxides of Cu, Co, Fe, Ni, Mn, Cr and additives of oxides, sulfides, metal compounds, and silicates for 0 to 15%. The thickness of the ceramic composite material as deposited is generally in a range of about 0.03 to 0.25 millimeters pending the distribution and the number of passes utilized to form the patterned frit material.

Exemplary conductive pastes include a conductive metal such palladium, silver, silver palladium, platinum, gold, or the like. Additionally, the paste can include a spreading agent, which are generally known in the art. The thickness of the conductive paste layers as deposited are generally in a range of about 5 microns to about 30 microns.

The piezoelectric material can be lead zirconium titanate, calcium titanate, barium titanate, lead titanate, strontium titanate, or the like. The thickness of the piezoelectric material as deposited is generally in a range of about 5 to about 30 microns as needed.

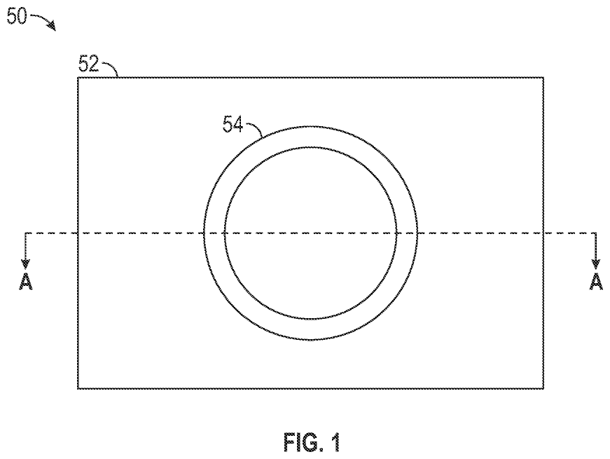

FIG. 1 is a top-down view of an assembly 50 including a laminated glass structure 52 having a circular-shaped piezoelectric actuator 54 printed onto a selected one of the inner glass surfaces between opposing glass panels in accordance with one or more embodiments of the present disclosure. The printed piezoelectric actuator 54 is not intended to be limited to a circular shape and can be of any ring-shape. By way of example, the ring-shaped three-dimensionally printed piezoelectric actuators can be patterned in the shape of an oval; a polygon such as a hexagon; irregular ring shapes; or the like, which can be repeated at various locations on the inner glass surface. The repeating pattern is not intended to be limited and can include a variety of different shapes or the same shape repeated throughout the laminated glass structure. The printing of the piezoelectric actuators on glass surfaces can be done in an off-line process subsequent to or during manufacture of the laminated glass structure, which advantageously eliminates the need for installation of the traditional cone and coil speaker systems outside of the laminated glass structure, thereby increasing process efficiency to manufacture the vehicle.

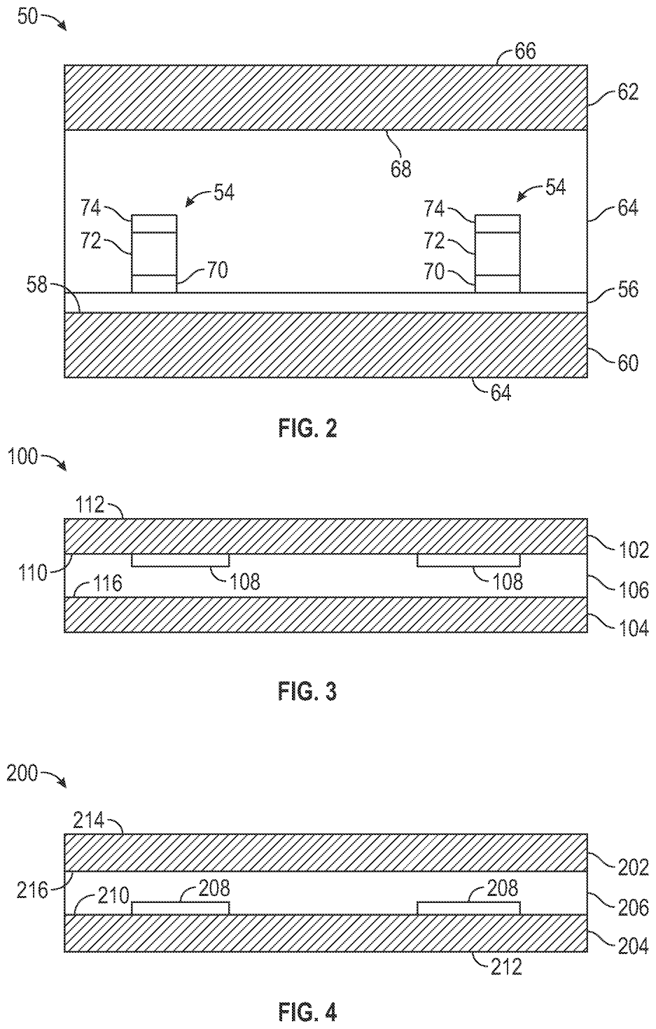

Turning now to FIG. 2, there is depicted an enlarged cross-sectional view of the laminated glass structure assembly 50 taken along lines A-A of FIG. 1. The laminated glass structure assembly 50 includes first and second glass panels 60, 62, respectively, and a laminating material 65 therebetween for bonding the first and second glass panels 60, 62, respectively, together. The first glass panel 60 includes an outer surface 64 and an inner surface 58. The second glass panel 62 also includes an outer surface 66 and an inner surface 68. The ring-shaped piezoelectric actuator 54 is formed on a glass frit layer 56 deposited on a selected inner surface of a glass panel, (e.g., inner surface 58 of first glass panel 60 as shown). The glass frit layer 56 can be deposited and patterned to have a shape similar to the ring-shaped piezoelectric actuator 54 or can be a continuous layer. Generally, the width of the ring-shaped piezoelectric actuator 54 is less than a width of the glass frit layer 56. The glass frit layer 56 can be a glass or ceramic material and selected to be opaque or semi-transparent depending on the composition. Forming the piezoelectric actuator 54 includes deposition of a first conductive paste layer 70 in a desired ring shape onto the patterned glass frit layer 56. A piezoelectric material 72 is then printed on the first conductive paste layer 70 followed by a deposition of second conductive paste layer 74 on the printed piezoelectric material 72 to form the piezoelectric actuator 54. As previously noted, the different layers can be robotically deposited onto the selected inner surface of a glass panel, (e.g., inner surface 58 of the first glass panel 60 as shown).

As shown, the piezoelectric actuator 54 has a thickness less than the laminating material 65 and is off axis relative to a longitudinal centerline between the opposing first and second glass panels 60, 62, respectively. Additionally, the piezoelectric actuator 54 is configured such that the glass frit layer 56 is wider than the width dimension of the piezoelectric actuator 54.

There are numerous non-limiting methods to print the piezoelectric material onto a glass or ceramic substrate, depending on the type of piezoelectric material and the desired shape and size of the piezoelectric actuator. By way of example, inkjet printing can be used to form the piezoelectric actuator using an inkjet printer to deposit droplets of a piezoelectric ink such as PVDF-TrFE onto a substrate including conductive electrodes. The ink is then sintered and tempered to form a piezoelectric layer. In another example, a three-dimensional (3-D) printer can be used to fabricate the ring-shaped piezoelectric actuators layer by layer. The piezoelectric materials used in the piezoelectric actuators can be either polymers, ceramics, or composites. The 3-D printing can be done by either poling the piezoelectric materials before, during, or after the printing process. Poling is the process of applying an electric field to align the electric dipoles in the piezoelectric materials and enhance their piezoelectric effect. In other examples, a screen printer can be used to deposit layers of piezoelectric paste (such as lead zirconium titanate) onto a substrate along with electrodes (i.e., the conductive layers). The paste is then fired to form the piezoelectric actuator.

Turning now to FIG. 3, there is depicted a cross sectional view of a laminated glass structure 100 in accordance with one or more embodiments of the present disclosure. The laminated glass structure 100 includes a first glass panel 102, a second glass panel 104, a laminate layer 106 intermediate the first and second glass panels 102, 104, respectively, and a ring-shaped piezoelectric actuator 108 provided on an inner surface 110 of the first glass panel 102. The piezoelectric actuator 108 is printed at a desired location on a frit material (not shown) as generally described in prior embodiments to the inner surface 110 of the first glass panel 102 and embedded within the laminate layer 106 when the first and second glass panels 102, 104 and the laminate layer 106 are exposed to heat and pressure to form the laminated glass structure 100. The first glass panel 102 also includes an outer surface 112 facing the exterior environment when in use. The second glass panel 104 includes an outer surface 114 facing the vehicle interior and an inner surface 116. An electrical signal provided to the piezoelectric actuator 108 can be utilized to produce sound from the laminate glass structure and into the interior of the vehicle. By way of example, the laminate glass structure 100 can be utilized as a roofing panel (fixed or moving) and can include multiple piezoelectric actuators 108 spaced about the panel in a decorative pattern to provide sound directly above the occupants of the vehicle without affecting trim panel space.

In FIG. 4, there is depicted a cross sectional view of a laminated glass structure 200 in accordance with one or more embodiments of the present disclosure. The laminated glass structure 200 includes a first glass panel 202, a second glass panel 204, a laminate layer 206 intermediate the first and second glass panels 202, 204, respectively, and a piezoelectric actuator 208 provided on an inner surface 210 of the second glass panel 204. The second glass panel 204 also includes an outer surface 212 facing the interior of the vehicle. The ring-shaped piezoelectric actuator 208 is printed at a desired location on a frit material (not shown) to the inner surface 210 of the second glass panel 204 and embedded within the laminated glass structure 200 when the first and second glass panels 202, 204, respectively, and the laminate layer 206 are exposed to heat and pressure. The first glass panel 202 also includes an outer surface 214 facing the exterior environment when in use and an inner surface 216. An electrical signal provided to the piezoelectric actuators 208 can be utilized to produce sound from the laminate glass structure 200 and into the interior of the vehicle.

In the above embodiments, when ring-shaped piezoelectric actuators are utilized within a laminated glass structure, the piezoelectric actuators can be printed at the same plane, (i.e., on a patterned frit material deposited onto the same inner surface of the outer glass panel or the inner glass panel and are generally offset relative to a centerline longitudinally extending between the first and second glass panel).

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A laminated glass structure for a vehicle comprising:
an outer glass panel including an outer surface facing an environment about the vehicle and an inner surface;
an inner glass panel including an outer surface facing an interior of the vehicle and an inner surface;
a laminating material intermediate the outer and inner glass panels bonded to the inner surfaces of the outer and inner glass panels; and
at least one printed ring-shaped piezoelectric actuator on a frit material formed on a selected one of the inner surfaces, wherein the at least one printed ring-shaped piezoelectric actuator and the frit material are embedded within the laminating material and offset relative to a centerline longitudinally extending between the outer and inner glass panels.

2. The laminated glass structure of claim 1, wherein the at least one printed ring-shaped piezoelectric actuator is printed on the inner surface of the outer glass panel.

3. The laminated glass structure of claim 1, wherein the at least one printed ring-shaped piezoelectric actuator is printed on the inner surface of the inner glass panel.

4. The laminated glass structure of claim 1, wherein the at least one of the printed ring-shaped piezoelectric actuators is printed on the inner surface of the inner glass panel and printed on the inner surface of the outer glass panel.

5. The laminated glass structure of claim 1, wherein the at least one printed ring-shaped piezoelectric actuator comprises a first conductive layer on the frit material, a piezoelectric material on the first conductive layer, and a second conductive layer on the piezoelectric material.

6. The laminated glass structure of claim 1, wherein the at least one printed ring-shaped piezoelectric actuator has an oval-shape, a circular shape, and/or a polygonal shape.

7. The laminated glass structure of claim 1, wherein the laminating material comprises polyvinyl butyral resin or ethylene vinyl acetate.

8. The laminated glass structure of claim 1 further comprising a plastic layer configured to provide solar reflectivity within the laminating material and intermediate the inner and outer glass panels.

9. The laminated glass structure of claim 1, wherein the outer glass panel has a thickness within a range of about 1.6 to about 3.5 millimeters, the inner glass panel has a thickness of the about 0.7 millimeters to about 3.5 millimeters, the laminating material has a thickness in a range of about 0.3 millimeters to about 2.0 millimeters, and the at least one printed ring-shaped piezoelectric actuator has a thickness less than the laminating material.

10. The laminated glass structure of claim 1, wherein the frit material has a width greater than a width of the printed ring-shaped piezoelectric actuator.

11. The laminated glass structure of claim 1, wherein the frit material is printed onto the selected inner glass surface.

12. The laminated glass structure of claim 1, wherein the frit material is semi-transparent.

13. The laminated glass structure of claim 5, wherein the piezoelectric material comprises lead zirconium titanate.

14. A process of forming a laminated glass structure for a vehicle comprising:
printing a ring pattern of a frit material on an inner surface of a selected glass panel;
printing a first conductive layer onto the ring pattern of the frit material ring pattern;
printing a piezoelectric material onto the first conductive layer;
printing a second conductive layer onto the piezoelectric material to form a piezoelectric actuator;
stackedly arranging the selected glass panel, a sheet of laminating material; and another glass panel, wherein the inner surface of the selected glass panel contacts the sheet of laminating material and the another glass panel includes an inner surface contacting the sheet of laminating material such that the sheet of laminating material is sandwiched therebetween; and
applying heat and pressure to laminate the selected glass panel to the another glass panel, wherein the piezoelectric actuator on the ring pattern of the frit material have a height dimension less than a thickness of the sheet of laminating material.

15. The process of claim 14, wherein the sheet of laminating material comprises polyvinyl butyral resin or ethylene vinyl acetate.

16. The process of claim 14, wherein printing the frit material, the first and second conductive layers and the piezoelectric material comprises robotically depositing droplets of the frit material, the first and second conductive layers, and the piezoelectric material to form the piezoelectric actuator.

17. The process of claim 14, wherein printing the frit material, the first and second conductive layers and the piezoelectric material comprises ink jet printing, screen printing, additive manufacturing, etching or combinations including at least one thereof.

18. The process of claim 14, wherein the piezoelectric material comprises lead zirconium titanate.

19. The process of claim 14, wherein the ring pattern comprises a circular-shape, an oval-shape, or a polygonal-shape.

20. A laminated glass structure for a vehicle, the laminated glass structure comprising:
an outer glass panel having a thickness of about 1.6 to about 3.5 millimeters, the outer glass panel including an outer surface exposed to an environment about the vehicle and an inner surface;
an inner glass panel having a thickness of about 0.7 millimeters to about 3.5 millimeters, the inner glass panel including an inner surface and an outer surface exposed an interior of the vehicle;
a laminating material having a thickness of about 0.3 millimeters to about 2 millimeters between the outer glass panel and the inner glass panel and in contact with the inner surfaces of the outer and inner glass panels, wherein the laminating material comprises polyvinyl butyral resin or ethylene vinyl acetate; and
at least one printed piezoelectric actuator is embedded partly in the laminating material and has a thickness less than the laminating material, wherein the at least one printed piezoelectric actuator is in a shape of a ring having a thickness less than an actual thickness of the laminating material, wherein the at least one printed piezoelectric actuator is offset relative to a centerline extending between the inner surfaces of the outer and inner glass panels and are in contact with a selected one of the inner surfaces of the outer glass panel or the inner glass panel, and
wherein the laminated glass structure forms a fixed glass roof system, a movable glass roof system, a front windshield, a rear quarter glass, a side moving glass, and/or a non-movable side glass.
